(19) United States
(12) Patent Application Publication
(10) Pub. No.: US 2011/0057278 A1
(43) Pub. Date: Mar. 10, 2011

(54) X-RAY DETECTOR USING LIQUID CRYSTAL DEVICE

(76) Inventors: Sang Hwa KIM, Gyunggi-do (KR); Bae Kyun Kim, Gyunggi-do (KR); Kwang Seok Choi, Gyunggi-do (KR); Sang Su Hong, Gyunggi-do (KR); Chang Yun Lee, Gyunggi-do (KR); Kiy Eo Kim, Gyunggi-do (KR)

(21) Appl. No.: 12/609,509

(22) Filed: Oct. 30, 2009

(30) Foreign Application Priority Data
Sep. 9, 2009 (KR) 10-2009-0084999

(51) Int. Cl. H01L 31/08

(52) U.S. Cl. 257/432; 257/E31.092

(57) ABSTRACT

An X-ray detector includes a first substrate having a bottom surface on which a first electrode is formed. A second substrate has a top surface on which a second electrode and a polyimide layer are sequentially formed. A photoconductive layer is formed on a bottom surface of the first electrode and generates electron-hole pairs. A reflective layer is formed on a bottom surface of the photoconductive layer. A liquid crystal polymer layer is formed on a bottom surface of the reflective layer, and peaks and valleys are alternately formed on a bottom surface of the liquid crystal polymer layer. A liquid crystal layer is formed between the liquid crystal polymer layer and the polyimide layer, and liquid crystal molecules are aligned in a direction in which the peaks and valleys on the bottom surface are arranged.

### CROSS REFERENCE TO RELATED APPLICATION

This application claims the benefit of Korean Patent Application No. 10-2009-0084999, filed on Sep. 9, 2009, entitled “X-Ray Detector Using Liquid Crystal Device”, which is hereby incorporated by reference in its entirety into this application.

### BACKGROUND OF THE INVENTION

1. Technical Field

The present invention relates to an X-ray detector using a liquid crystal device.

2. Description of the Related Art

Generally, X-ray detection apparatuses are devices for detecting X-rays passing through an examination target and determining the status of the examination target.

Schemes using Thin Film Transistor (TFT) technology have been generally applied to such X-ray detection apparatuses. However, schemes using TFT technology are implemented to include millions of pixels, thus resulting in limitations in universalizing the schemes due to the problems of electric noise and high cost as well as the problem of complicated circuitry.

Accordingly, X-ray detection apparatuses using a liquid crystal device, as shown in FIG. 1, have recently been proposed.

FIG. 1 is a diagram showing a conventional X-ray detection apparatus using a liquid crystal device.

As shown in FIG. 1, the conventional X-ray detection apparatus using a liquid crystal device is configured such that X-rays generated by an X-ray generation unit 140 are incident on an X-ray detector 100.

The X-ray detector 100 is configured such that, in order to apply bias voltages both to the photoconductive layer 110 and to a liquid crystal layer 112 in which liquid crystal molecules are aligned in a specific direction, the photoconductive layer 110 and the liquid crystal layer 112 are connected in series with each other, a first electrode 114a is formed on the top surface of the photoconductive layer 110, and a second electrode 114b is formed on the bottom surface of the liquid crystal layer 112.

Further, a first substrate 116a made of a transparent material is formed on the top surface of the first electrode 114a, and a second substrate 116b made of a transparent material is formed on the bottom surface of the second electrode 114b.

Furthermore, a reflective layer 118 is formed on the bottom surface of the photoconductive layer 110, and a space between the reflective layer 118 and the liquid crystal layer 112 as well as a space between the liquid crystal layer 112 and the second electrode 114b are coated with polyimide 120a and 120b.

Meanwhile, in the X-ray detector 100, a space for the liquid crystal layer 112 is defined by spacers 130.

In such an X-ray detector 100, electron-hole pairs are formed in the photoconductive layer 110, as shown in FIG. 2, by the X-rays generated by and input from the X-ray generation unit 140. Electrons and holes are moved to both ends of the photoconductive layer 110 due to the voltages applied to the first electrode 114a and the second electrode 114b. Further, because of the movement of the electrons and holes, a spatial potential difference occurs in the upper portion of the liquid crystal layer 112, thus inducing non-uniform behavior of liquid crystal molecules.

Accordingly, an X-ray image is directly formed on the liquid crystal layer 112 and is detected by an external light source and a sensor, and thus the X-ray image is implemented.

However, such a conventional X-ray detector 100 is problematic because light transmission loss occurs due to the difference between the temperature of a process for forming the alignment film of the liquid crystal layer 112 and the temperature of a process for depositing the photoconductive layer 110.

In the case of amorphous selenium generally used for the photoconductive layer 110, when the process temperature exceeds 60° C., crystallization is performed. Such crystallization may result in negative effects which greatly deteriorate the sensitivity of the X-ray detector 100.

Therefore, the process temperature must be maintained at a low temperature.

In contrast, since the process temperature of the polyimide 120a and 120b widely used for the alignment film of the liquid crystal layer 112 reaches 270° C., the process for forming the alignment film of the liquid crystal layer 112 and the process for depositing the photoconductive layer 110 cannot be compatible with each other. Therefore, there is a need to join the liquid crystal layer 112 and the photoconductive layer 110 together after the above two processes have been separately performed, or to adopt a method other than a spin coating method for the polyimide 120a and 120b used for the alignment film.

Further, the conventional X-ray detector 100 is problematic in that, since it does not present a solution to light transmission loss that may occur when incident light passes through the liquid crystal layer 112, elliptical polarization occurs when incident light emitted from an external light source (that is, the X-ray generation unit) passes through the liquid crystal layer 112, so that light transmission loss is caused, thus deteriorating the sensitivity of X-ray images.

### SUMMARY OF THE INVENTION

Accordingly, the present invention has been made keeping in mind the above problems occurring in the prior art, and the present invention is intended to provide an X-ray detector using a liquid crystal device, which solves the problem of the process temperature of an alignment film formation process by aligning liquid crystal molecules using a liquid crystal polymer, and which reduces light transmission loss and improves the sensitivity of the X-ray detector by using the liquid crystal polymer as a phase delay plate.

In accordance with an aspect of the present invention, there is provided an X-ray detector, comprising a first substrate having a bottom surface on which a first electrode is formed; a second substrate having a top surface on which a second electrode and a polyimide layer are sequentially formed; a photoconductive layer formed on a bottom surface of the first electrode and configured to generate electron-hole pairs using externally radiated light; a reflective layer formed on a bottom surface of the photoconductive layer; a liquid crystal polymer layer formed on a bottom surface of the reflective layer and configured such that peaks and valleys are alternately formed at regular intervals on a bottom surface of the liquid crystal polymer layer; and a liquid crystal layer formed between the liquid crystal polymer layer and the polyimide layer and configured such that liquid crystal molecules are aligned in a direction in which the peaks and valleys formed on the bottom surface of the liquid crystal polymer layer are arranged.

In the X-ray detector according to an embodiment of the present invention, the liquid crystal polymer layer delays a phase of light having passed through the liquid crystal layer by a ¼ wavelength and converts the delayed light into linearly polarized light.

In the X-ray detector according to an embodiment of the present invention, the liquid crystal layer is formed using an Optically Compensated Bend (OCB) mode.

In accordance with another aspect of the present invention, there is provided an X-ray detector, comprising a first substrate having a bottom surface on which a first electrode is formed; a second substrate having a top surface on which a second electrode is formed; a photoconductive layer formed on a bottom surface of the first electrode and configured to generate electron-hole pairs using externally radiated light; a reflective layer formed on a bottom surface of the photoconductive layer; a first liquid crystal polymer layer formed on a bottom surface of the reflective layer and configured such that peaks and valleys are alternately formed at regular intervals on a bottom surface of the first liquid crystal polymer layer; a second liquid crystal polymer layer formed on a top surface of the second electrode and configured such that peaks and valleys are alternately formed at regular intervals on a top surface of the second liquid crystal polymer layer in a same direction as a direction in which the peaks and valleys formed on the bottom surface of the first liquid crystal polymer layer are arranged; and a liquid crystal layer formed between the first liquid crystal polymer layer and the second liquid crystal polymer layer and configured such that liquid crystal molecules are aligned in the direction in which the peaks and valleys formed on the bottom surface of the first liquid crystal polymer layer and the top surface of the second liquid crystal polymer layer are arranged.

In the X-ray detector according to an embodiment of the present invention, each of the first and second liquid crystal polymer layers delays a phase of light having passed through the liquid crystal layer by a ¼ wavelength and converts the delayed light into linearly polarized light.

In the X-ray detector according to an embodiment of the present invention, the liquid crystal layer is formed using an Optically Compensated Bend (OCB) mode.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram showing a conventional X-ray detection apparatus;

FIG. 2 is a diagram showing a process for forming electron-hole pairs in the X-ray detector of FIG. 1;

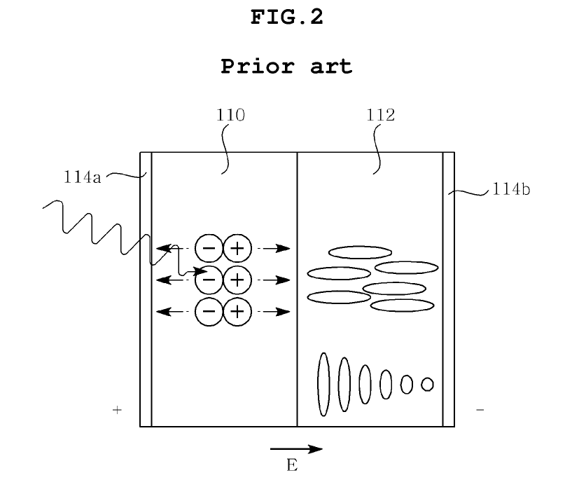

FIG. 3 is a diagram showing an X-ray detector using a liquid crystal device according to an embodiment of the present invention;

FIG. 4 is a diagram showing an X-ray detector using a liquid crystal device according to another embodiment of the present invention;

FIG. 5 is a diagram showing an X-ray detection apparatus using the X-ray detector of FIGS. 3 and 4; and

FIG. 6 is a diagram showing the polarization characteristics of the liquid crystal polymer layer of FIGS. 3 and 4 using a Poincare sphere.

### DESCRIPTION OF THE PREFERRED EMBODIMENTS

Hereinafter, embodiments of the present invention will be described in detail with reference to the attached drawings.

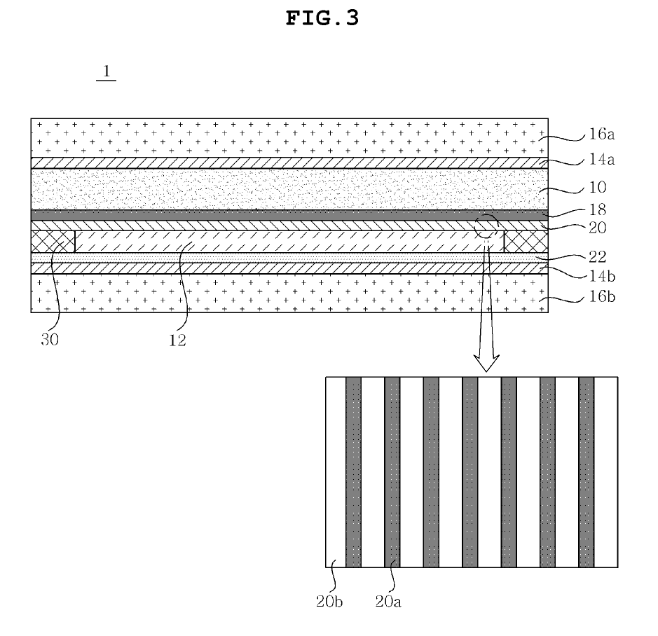

FIG. 3 is a diagram showing an X-ray detector according to an embodiment of the present invention.

As shown in FIG. 3, an X-ray detector 1 according to an embodiment of the present invention includes a first substrate 16a which is an upper glass substrate, a photoconductive layer 10, a liquid crystal polymer layer 20, a liquid crystal layer 12, a polyimide layer 22, and a second substrate 16b which is a lower glass substrate.

The first substrate 16a is made of transparent glass, and a first electrode 14a made of an Indium Tin Oxide (ITO) material is formed on the bottom surface of the first substrate 16a.

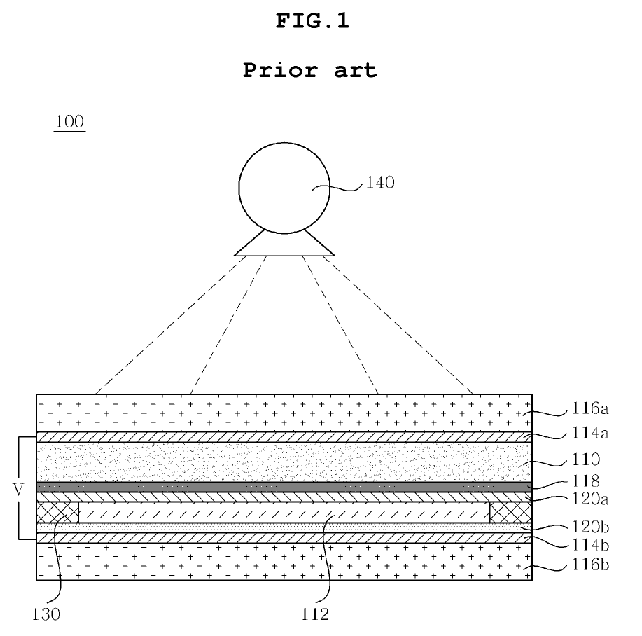

The photoconductive layer 10 is formed between the first electrode 14a and a reflective layer 18 and configured to generate electron-hole pairs using externally radiated light (for example, X-rays generated by the X-ray generation unit of FIG. 1).

Such a photoconductive layer 10 is made of amorphous selenium.

The liquid crystal polymer layer 20 is formed between the liquid crystal layer 12 and the reflective layer 18, and configured such that peaks 20a and valleys 20b, required to align the liquid crystal molecules of the liquid crystal layer 12 in a specific direction, are alternately arranged at regular intervals on the surface of the liquid crystal polymer layer 20, facing the liquid crystal layer 12.

In this case, the peaks 20a and valleys 20b are formed on the liquid crystal polymer layer 20 using an imprint method.

Thanks to the peaks 20a and the valleys 20b formed on the surface of the liquid crystal polymer layer 20, facing the liquid crystal layer 12, the liquid crystal polymer layer 20 functions not only to align the liquid crystal molecules of the liquid crystal layer 12 in a specific direction, but also to convert the polarized component of light having passed through the liquid crystal layer 12 into a linearly polarized component.

For this function, the liquid crystal polymer layer 20 is implemented as a 1/4 phase delay plate (quarter wave plate).

That is, the liquid crystal polymer layer 20 is implemented as the quarter wave plate through the adjustment of the refractive index and thickness of a liquid crystal. When light emitted from the external light source passes through the liquid crystal layer 12, the quarter wave plate delays the phase of the light having passed through the liquid crystal layer 12 by a ¼ wavelength and converts the delayed light into linearly polarized light.

Such a liquid crystal polymer layer 20 is attached to the bottom surface of the reflective layer 18 at a temperature similar to the temperature of the process for depositing the photoconductive layer 10 made of amorphous selenium.

The liquid crystal layer 12 is formed in a space defined by spacers 30 formed between the liquid crystal polymer layer 20 and the polyimide layer 22 (to have a thickness of, for example, about 5 μm). The liquid crystal molecules are aligned in the direction in which the peaks 20a and the valleys 20b formed on the bottom surface of the liquid crystal polymer layer 20 are arranged.

Such a liquid crystal layer 12 is generally formed using a Twisted Nematic (TN) mode. However, in the present invention, it is preferable to use an Optically Compensated Bend (OCB) mode enabling fast response because it does not have the reverse flow, unlike the TN mode.

The second substrate 16b is made of transparent glass, and configured such that the second electrode 14b, made of an ITO material, and the polyimide layer 22 are sequentially formed on the top surface of the second substrate 16b.

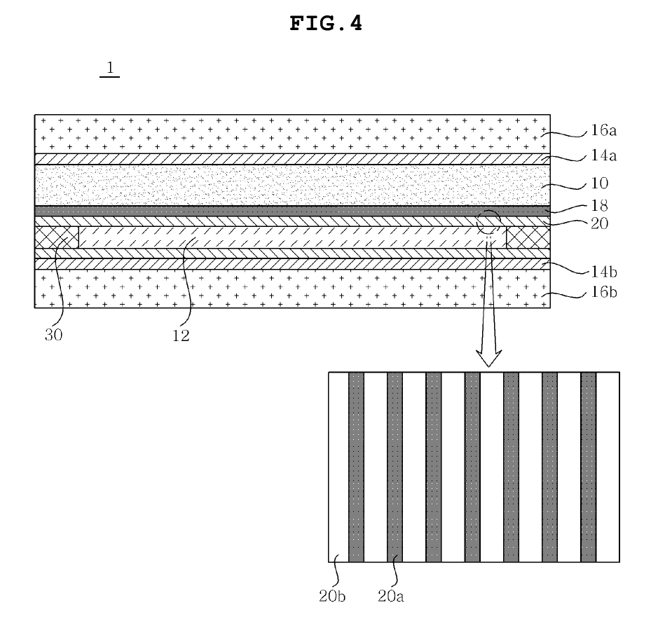

FIG. 4 is a diagram showing an X-ray detector according to another embodiment of the present invention.

As shown in FIG. 4, an X-ray detector 1 according to another embodiment of the present invention includes a first substrate 16a, a photoconductive layer 10, liquid crystal polymer layers 20, a liquid crystal layer 12, and a second substrate 16b.

The first substrate 16a is made of transparent glass, and a first electrode 14a made of an ITO material is formed on the bottom surface of the first substrate 16a.

The photoconductive layer 10 is formed between the first electrode 14a and a reflective layer 18 and configured to generate electron-hole pairs using externally radiated light (for example, X-rays generated by the X-ray generation unit of FIG. 1).

Such a photoconductive layer 10 is made of amorphous selenium.

A first liquid crystal polymer layer 20 is formed between the liquid crystal layer 12 and the reflective layer 18, and is configured such that peaks 20a and valleys 20b, required to align the liquid crystal molecules of the liquid crystal layer 12 in a specific direction, are alternately arranged at regular intervals on the surface of the first liquid crystal polymer layer 20, facing the liquid crystal layer 12 (that is, the bottom surface of the first liquid crystal polymer layer).

A second liquid crystal polymer layer 20 is formed between the liquid crystal layer 12 and the second electrode 14b, and is configured such that peaks 20a and valleys 20b, required to align the liquid crystal molecules of the liquid crystal layer 12 in the specific direction, are alternately arranged at regular intervals on the surface of the second liquid crystal polymer layer 20, facing the liquid crystal layer 12 (that is, the top surface of the second liquid crystal polymer layer).

That is, the peaks 20a and valleys 20b formed on the top surface of the second liquid crystal polymer layer 20 are arranged in the same direction as the direction in which the peaks 20a and valleys 20b formed on the bottom surface of the first liquid crystal polymer layer 20 are arranged.

As described above, the peaks 20a and valleys 20b formed both on the first liquid crystal polymer layer 20 and on the second liquid crystal polymer layer 20 are formed using an imprint method.

Meanwhile, thanks to the peaks 20a and valleys 20b formed on the bottom surface of the first liquid crystal polymer layer 20 and the top surface of the second liquid crystal polymer layer 20, the first and second liquid crystal polymer layers 20 not only allow the liquid crystal molecules of the liquid crystal layer 12 to be aligned in a specific direction, but also convert the polarized component of the light having passed through the liquid crystal layer 12 into a linearly polarized component.

For this operation, each of the first liquid crystal polymer layer 20 and the second liquid crystal polymer layer 20 is implemented as a 1/4 phase delay plate (quarter wave plate).

In other words, when light emitted from the external light source passes through the liquid crystal layer 12, the first and second liquid crystal polymer layers 20 delay the phase of the light having passed through the liquid crystal layer 12 by a ¼ wavelength, and convert the delayed light into linearly polarized light.

The first liquid crystal polymer layer 20 is attached to the bottom surface of the reflective layer 18 at a temperature similar to the temperature of a process for depositing the photoconductive layer 10 made of amorphous selenium. The second liquid crystal polymer layer 20 is attached to the top surface of the second electrode 14b at a temperature similar to the temperature of the process for depositing the photoconductive layer 10.

The liquid crystal layer 12 is formed in a space defined by spacers 30 formed between the first and second liquid crystal polymer layers 20 (to have a thickness of, for example, about 5 μm). The liquid crystal molecules are aligned in the direction in which the peaks 20a and valleys 20b, formed on the bottom surface of the first liquid crystal polymer layer 20, and the peaks 20a and valleys 20b, formed on the top surface of the second liquid crystal polymer layer 20, are arranged.

Such a liquid crystal layer 12 is generally formed using a TN mode. However, in the present invention, it is preferable to use an OCB mode enabling fast response because the reverse flow of the OCB mode is smaller than that of the TN mode.

The second substrate 16b is made of transparent glass, and the second electrode 14b, made of an ITO material, is formed on the top surface of the second substrate 16b.

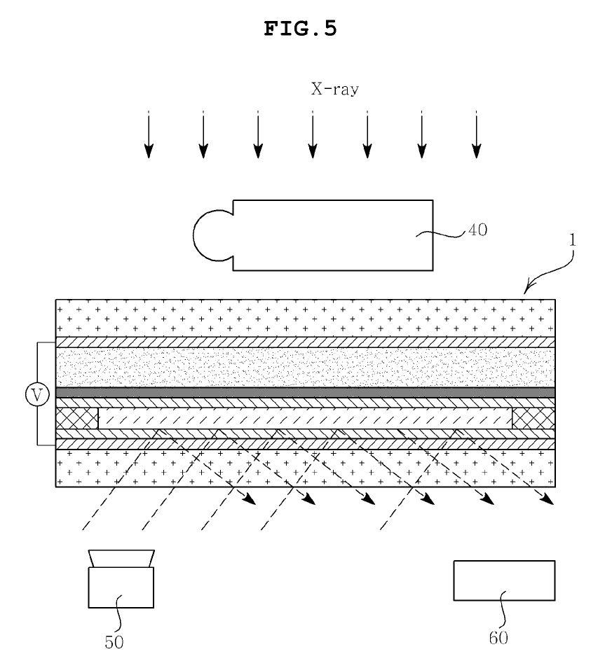

A method of implementing an image of an examination target using the X-ray detector having the above construction will be described with reference to FIG. 5.

An examination target 40 is arranged on the side of the second substrate 16b on which the photoconductive layer 10 is formed, and bias voltages are applied to the first electrode 14a and the second electrode 14b.

Thereafter, when X-rays are applied to the examination target 40, X-rays having passed through the examination target 40 cause polarization on the photoconductive layer 10 while passing through the photoconductive layer 10.

That is, the photoconductive layer 10 generates electron-hole pairs using the X-rays generated by an X-ray generation unit (not shown).

In this case, electron-hole pairs generated in the photoconductive layer 10 are moved to both ends of the photoconductive layer 10 by the voltages applied to the first electrode 14a and the second electrode 14b.

That is, electrons of the electron-hole pairs generated in the photoconductive layer 10 are moved to the first electrode 14a to which a positive (+) voltage is applied, and holes are moved to an upper portion of the liquid crystal layer 12 (that is, in the direction of the second electrode 14b).

Accordingly, a potential difference occurs between the upper portion and the lower portion (that is, the direction of the second electrode 14b) of the liquid crystal layer 12. Due to the potential difference, non-uniform behavior of the liquid crystal molecules is induced (that is, the states of liquid crystal molecules vary due to the potential difference occurring between the upper and lower portions of the liquid crystal layer 12).

In this case, when the light emitted from a light source 50 disposed opposite the examination target 40, that is, on the side of the first substrate 16a, is radiated onto the X-ray detector 1, the light emitted from the light source 50 passes through the liquid crystal layer 12, and is then reflected back from the reflective layer 18.

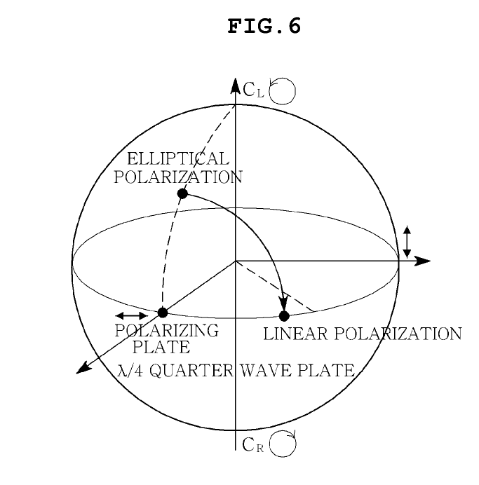

Meanwhile, the light having passed through the liquid crystal layer 12 is converted into light of various polarized components, such as a linearly polarized component, an elliptically polarized component, and a circularly polarized component. When the light having passed through the liquid crystal layer 12 is linearly polarized light, the liquid crystal polymer layers 20 transmit the light having passed through the liquid crystal layer 12 to the reflective layer 18. When the light having passed through the liquid crystal layer 12 is elliptically or circularly polarized light, the liquid crystal polymer layers 20 delay the phase of the light having passed through the liquid crystal layer 12 by a ¼ wavelength and convert the delayed light into linearly polarized light, as shown in FIG. 6, and thereafter transmit the linearly polarized light to the reflective layer 18.

In this case, the reflective layer 18 reflects the linearly polarized light transmitted through the liquid crystal polymer layers 20. A photodetector 60 detects and analyzes the light reflected from the reflective layer 18, thus determining the status of the examination target 40.

As described above, since the X-ray detector according to the embodiment of the present invention enables liquid crystal molecules to be aligned using the liquid crystal polymer, a process for forming the alignment film of the liquid crystal layer 12 and a process for depositing the photoconductive layer 10 can be compatibly performed, thus solving the problem of process temperature. Further, since the X-ray detector enables the phase of light to be delayed in various forms according to the optical design of the liquid crystal polymer, light transmission loss can be reduced, thus improving the sensitivity of X-ray images.

Accordingly, the present invention is advantageous in that, since liquid crystal molecules are aligned using a liquid crystal polymer, a process for forming the alignment film of a liquid crystal layer and a process for depositing a photoconductive layer can be compatibly performed, thus solving the problem of process temperature, and in that, since the phase of light can be delayed in various forms according to the optical design of the liquid crystal polymer, light transmission loss can be reduced, thus improving the sensitivity of X-ray images.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. An X-ray detector, comprising:
a first substrate having a bottom surface on which a first electrode is formed;
a second substrate having a top surface on which a second electrode and a polyimide layer are sequentially formed;
a photoconductive layer formed on a bottom surface of the first electrode and configured to generate electron-hole pairs using externally radiated light;
a reflective layer formed on a bottom surface of the photoconductive layer;
a liquid crystal polymer layer formed on a bottom surface of the reflective layer and configured such that peaks and valleys are alternately formed at regular intervals on a bottom surface of the liquid crystal polymer layer; and
a liquid crystal layer formed between the liquid crystal polymer layer and the polyimide layer and configured such that liquid crystal molecules are aligned in a direction in which the peaks and valleys formed on the bottom surface of the liquid crystal polymer layer are arranged.

2. The X-ray detector as set forth in claim 1, wherein the liquid crystal polymer layer delays a phase of light having passed through the liquid crystal layer by a ¼ wavelength and converts the delayed light into linearly polarized light.

3. The X-ray detector as set forth in claim 1, wherein the liquid crystal layer is formed using an Optically Compensated Bend (OCB) mode.

4. An X-ray detector, comprising:
a first substrate having a bottom surface on which a first electrode is formed;
a second substrate having a top surface on which a second electrode is formed;
a photoconductive layer formed on a bottom surface of the first electrode and configured to generate electron-hole pairs using externally radiated light;
a reflective layer formed on a bottom surface of the photoconductive layer;
a first liquid crystal polymer layer formed on a bottom surface of the reflective layer and configured such that peaks and valleys are alternately formed at regular intervals on a bottom surface of the first liquid crystal polymer layer;
a second liquid crystal polymer layer formed on a top surface of the second electrode and configured such that peaks and valleys are alternately formed at regular intervals on a top surface of the second liquid crystal polymer layer in a same direction as a direction in which the peaks and valleys formed on the bottom surface of the first liquid crystal polymer layer are arranged; and
a liquid crystal layer formed between the first liquid crystal polymer layer and the second liquid crystal polymer layer and configured such that liquid crystal molecules are aligned in the direction in which the peaks and valleys formed on the bottom surface of the first liquid crystal polymer layer and the top surface of the second liquid crystal polymer layer are arranged.

5. The X-ray detector as set forth in claim 4, wherein each of the first and second liquid crystal polymer layers delays a phase of light having passed through the liquid crystal layer by a ¼ wavelength and converts the delayed light into linearly polarized light.

6. The X-ray detector as set forth in claim 4, wherein the liquid crystal layer is formed using an Optically Compensated Bend (OCB) mode.
